(19) United States
(12) Patent Application Publication
(10) Pub. No.: US 2022/0056589 A1
(43) Pub. Date: Feb. 24, 2022

(54) ELECTROLESS SEMICONDUCTOR BONDING STRUCTURE, ELECTROLESS PLATING SYSTEM AND ELECTROLESS PLATING METHOD OF THE SAME

(71) Applicant: Advanced Semiconductor Engineering, Inc., Kaohsiung (TW)

(72) Inventors: Chun-Wei CHIANG, Kaohsiung (TW); Shin-Luh TARNG, Kaohsiung (TW); Chih-Pin HUNG, Kaohsiung (TW); Shiu-Chih WANG, Kaohsiung (TW); Yong-Da CHIU, Kaohsiung (TW)

(73) Assignee: Advanced Semiconductor Engineering, Inc., Kaohsiung (TW)

(21) Appl. No.: 17/000,239

(22) Filed: Aug. 21, 2020

(51) Int. Cl. C23C 18/16; H01L 21/67; H01L 21/768

(52) U.S. Cl. CPC C23C 18/1657; C23C 18/1682; H01L 21/76874; H01L 21/6723

(57) ABSTRACT

An electroless semiconductor bonding structure, an electroless plating system and an electroless plating method of the same are provided. The electroless semiconductor bonding structure includes a first substrate and a second substrate. The first substrate includes a first metal bonding structure disposed adjacent to a first surface of the first substrate. The second substrate includes a second metal bonding structure disposed adjacent to a second surface of the second substrate. The first metal bonding structure connects to the second metal bonding structure at an interface by electroless bonding and the interface is substantially void free.

### BACKGROUND

### 1. Technical Field

The present disclosure relates to a semiconductor structure, an electroless plating system, and an electroless plating method of the same, and more particularly, to an electroless semiconductor bonding structure, an electroless plating system, and an electroless plating method of the same that can improve reliability of internal electrical connections.

### 2. Description of the Related Art

Nowadays, techniques for incorporating more than one semiconductor substrates into a single semiconductor package to provide more functions are under progressively development. One semiconductor substrate (such as a unit substrate) may be stacked onto another. Because semiconductor substrates in a semiconductor package need internal electrical connections to communicate with each other, it would be desirable to provide a semiconductor structure that can provide it with reliable internal electrical connections where the semiconductor substrates can function properly or can achieve the required performances and at the same time satisfy the miniaturization requirement.

### SUMMARY

In an aspect, a method of electrolessly plating a substrate comprises disposing an electroless solution in a container; disposing a first substrate in the container, the first substrate having an exposed metal surface; removing a gaseous product from the container; and forming a metal layer on the exposed metal surface of the first substrate.

In an aspect, an electroless semiconductor bonding structure includes a first substrate and a second substrate. The first substrate includes a first metal bonding structure disposed adjacent to a first surface of the first substrate. The second substrate includes a second metal bonding structure disposed adjacent to a second surface of the second substrate. The first metal bonding structure connects to the second metal bonding structure at an interface by electroless bonding and the interface is substantially void free.

In an aspect, an electroless plating system includes an electroless solution container, a substrate container, and a vacuum pump. The vacuum pump connects to the substrate container.

### BRIEF DESCRIPTION OF THE DRAWINGS

FIG. 1A, FIG. 1B, and FIG. 1C illustrate a method of electrolessly plating a substrate.

FIG. 2 illustrates a cross-sectional view of an electroless semiconductor bonding structure according to some embodiments of the present disclosure.

FIG. 3 illustrates a cross-sectional view of an electroless semiconductor bonding structure according to some embodiments of the present disclosure.

FIG. 4 illustrates a cross-sectional view of an electroless semiconductor bonding structure according to some embodiments of the present disclosure.

FIG. 5(a) illustrates a cross-sectional view of an electroless semiconductor bonding structure according to some embodiments of the present disclosure.

FIG. 5(b) illustrates a cross-sectional view of an electroless semiconductor bonding structure according to some embodiments of the present disclosure.

FIG. 6 illustrates an electroless plating system according to some embodiments of the present disclosure.

### DETAILED DESCRIPTION

Spatial descriptions, such as “above,” “below,” “top,” and “bottom” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

In some embodiments, the present disclosure provides an electroless semiconductor bonding structure including a first substrate. The first substrate includes a first metal bonding structure disposed adjacent to a first surface of the first substrate. The first metal bonding structure includes a first electrical connector and a first electroless layer. The first electrical connector has a first side surface and a second side surface opposite to the first side surface. The first electroless layer surrounds the first electrical connector, where the first electroless layer has a first thickness at the first side surface of the first electrical connector and a second thickness at the second side surface of the first electrical connector. The first metal bonding structure may be successfully and electroless bonded to the respective second metal bonding structure continuously without any disruption where voids may be substantially free at or proximal to the interface between the first metal bonding structure and a respective second metal bonding structure and the difference between the first thickness and the second thickness may be controlled within a certain range, for example, within a range of about 1% to about 20% of the second thickness.

In some embodiments, the present disclosure provides a method of electrolessly plating a substrate by which an electroless semiconductor bonding structure mentioned above may be obtained.

In some embodiments, the present disclosure provides an electroless plating system by which a method of electrolessly plating a substrate mentioned above may be performed.

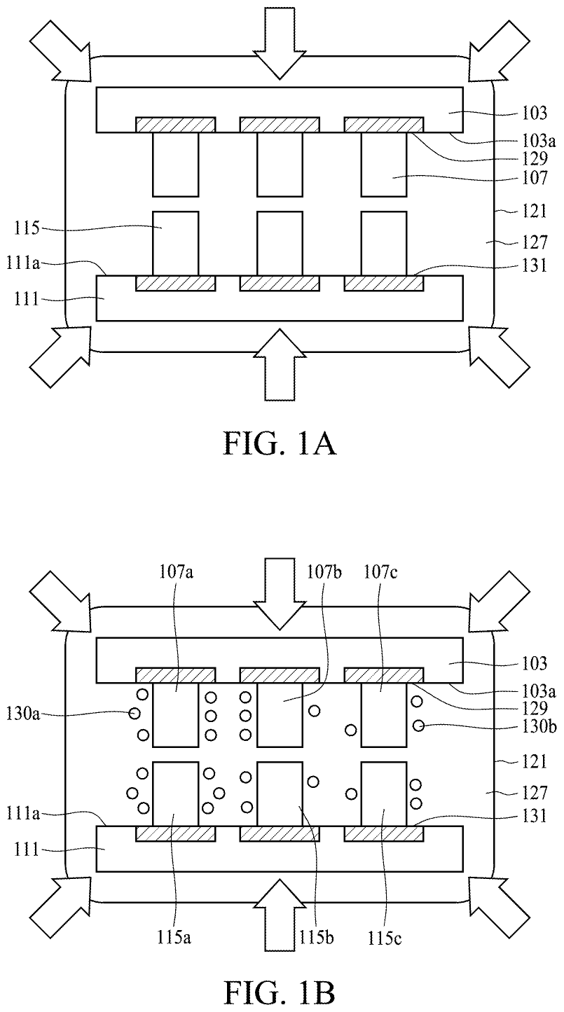

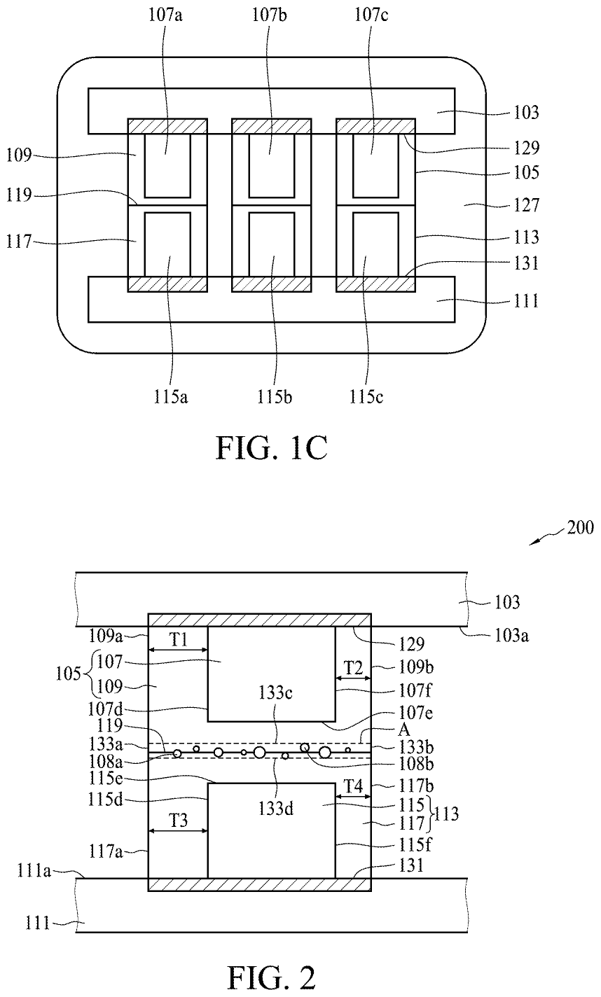

FIGS. 1A-1C illustrate a method of electrolessly plating a substrate.

Referring to FIG. 1A, a first substrate 103 and a second substrate 111 are provided in a container 121. The first substrate 103 has a first exposed metal surface 129. The second substrate 111 has a second exposed metal surface 131. The first exposed metal surface 129 and the second exposed metal surface 131 may be, for example, a contact pad of a trace or a ball pad. In some embodiments, the first exposed metal surface 129 and the second exposed metal surface 131 are a contact pad of a trace. The first substrate 103 may include a first electrical connector 107 disposed adjacent to a first surface 103a of the first substrate 103. The second substrate 111 may include a second electrical connector 115 disposed adjacent to a second surface 111a of the second substrate 111. The second surface 111a of the second substrate 111 may face the first surface 103a of the first substrate 103 with the first electrical connector 107 aligning with the respective second electrical connector 115.

An electroless solution 127 is disposed in the container 121 for carrying out an electroless plating process. The first substrate 103 and the second substrate 111 may be partially or wholly immersed in the electroless solution 127. The electroless plating process may be initiated after the first substrate 103 and the second substrate 111 are partially or wholly immersed in the electroless solution 127, where the plating metal (e.g., copper or nickel) may be deposited onto the first exposed metal surface 129, the second exposed metal surface 131, the first electrical connector 107, and the second electrical connector 115 to form a first electroless layer 109 and a second electroless layer 117 (shown in FIG. 1C).

In some embodiments, the first substrate 103 and the second substrate 111 are wholly immersed in the electroless solution 127. In some embodiments, the first substrate 103 is partially immersed in the electroless solution 127 (e.g., only the first electrical connector 107 and at least a portion of the first exposed metal surface 129 are immersed in the electroless solution 127) and the second substrate 111 is wholly immersed in the electroless solution 127.

The electroless solution 127 should be a solution suitable for plating the first substrate 103 and the second substrate 111. The first substrate 103 and the second substrate 111 may stand still in the container 121 with still electroless solution 127 (without flowing the electroless solution 127 in and out of the container 121). The first substrate 103 and the second substrate 111 may be placed in the electroless solution 127 in the container 121 that undergoes vibration. The first substrate 103 and the second substrate 111 may be placed in a flowing electroless solution 127 in the container 121.

The electroless solution 127 may be disposed in the container 121 continuously or intermittently. The electroless solution 127 may be disposed by flowing the electroless solution 127 from a first side of the container 121 to a second side of the container 121. The electroless solution 127 may be disposed by flowing the electroless solution 127 toward the first substrate 103 in at least two directions. In some embodiments, the electroless solution 127 is disposed by flowing the electroless solution 127 toward the first substrate 103 in opposite directions. In some embodiments, the electroless solution 127 is provided to the container 121 continuously by flowing the electroless solution 127 from an electroless solution container to the container 121 and out of the container 121.

In some embodiments where the electroless solution 127 is disposed in the container 121 continuously by flowing the electroless solution 127 from one side of the first electrical connector 107a, 107b, 107c toward the opposite side of the first electrical connector 107a, 107b, 107c, the first electroless layer 109 formed at one side of the first electrical connector 107a, 107b, 107c may be thicker than that formed at the opposite side of the first electrical connector 107a, 107b, 107c as the side of the first electrical connector 107a, 107b, 107c facing the flow direction will encounter the electroless solution more than the opposite side and thus will form thicker metal layer than the opposite side. As a result, as the first electroless layer 109 becomes thicker at one side of the first electrical connector 107a, 107b, 107c, it may hinder not only the formation of the first electroless layer 109 on the opposite side of the first electrical connector 107a, 107b, 107c, but also the formation of the first electroless layer on the other first electrical connector 107b, 107c on the back thereof. Therefore, in such embodiments, the first electroless layer 109 could not have a uniform thickness on the first electrical connector 107a, 107b, 107c, which may cause a metal bridge.

As a result, some first electrical connectors 107b, 107c may not be able to be well physically bonded to and electrically connected to the respective second electrical connectors 115b, 115c, which may impair the electrical connections between the first substrate 103 and the second substrate 111. The difference between the first electroless layer 109 at one side of the first electrical connector 107a, 107b, 107c and that at the opposite side may be larger than about 30% of the thickness of the first electroless layer 109 at the opposite side of the first electrical connector 107a, 107b, 107c. In some embodiments where the first substrate 103 and the second substrate 111 have a high arrangement density per area of the electrical connectors 107a, 107b, 107c, such difference may cause a metal bridge between adjacent electrical connectors 107a, 107b, 107c.

On the other hand, in some embodiments where the electroless solution 127 is disposed in the container 121 continuously by flowing the electroless solution 127 from different directions toward the first electrical connector 107a, 107b, 107c, the first electroless layer 109 may have a uniform thickness on the first electrical connector 107a, 107b, 107c as different surfaces of the first electrical connector 107a, 107b, 107c may encounter the electroless solution 127 with similar possibilities. As a result, the uniformity of the first electroless layer 109 on the first electrical connector 107a, 107b, 107c may be improved. In some embodiments, the difference between the first electroless layer 109 at one side of the first electrical connector 107a, 107b, 107c and that at the opposite side may be reduced to between about 1% and about 20% of the thickness of the first electroless layer 109 at the opposite side of the first electrical connector 107a, 107b, 107c. As a result, the electrical connections between the first substrate 103 and the second substrate 111 may be improved as less failure electrical connections.

Still referring to FIG. 1A, in some embodiments where the first substrate 103 and the second substrate 111 are disposed in the electroless solution 127 in the container 121 without flowing electroless solution (the first substrate 103 and the second substrate 111 stand still in a still electroless solution 127 or the electroless solution 127 is provided to the container 121 intermittently), the difference between the first electroless layer 109 at one side of the first electrical connector 107a, 107b, 107c and that at the opposite side may be reduced because the first electrical connector 107a, 107b, 107c may encounter the electroless solution from different directions with similar possibilities, which may form the first electroless layer 109 on the first electrical connector 107a, 107b, 107c more uniformly. In some embodiments, the difference between the first electroless layer 109 at one side of the first electrical connector 107a, 107b, 107c and that at the opposite side may be reduced to between about 1% and about 20% of the thickness of the first electroless layer 109 at the opposite side of the first electrical connector 107a, 107b, 107c. As a result, the electrical connections between the first substrate 103 and the second substrate 111 may be improved as less metal breakage occurred between adjacent electrical connectors 107a, 107b, 107c.

The electroless solution 127 may be provided to the container 121 intermittently by connecting the container 121 to an electroless solution container and controlling in and out of the electroless solution 127 from the electroless solution container by a switch or by means that can move the electroless solution 127 from one place to another, such as by manpower or any suitable transfer technology. The electroless solution 127 in the container 121 may be replaced after a certain period of time of the plating reaction (e.g., when the reactivity becomes slower or the reactants for plating are almost consumed).

Referring to FIG. 1B, a gaseous product 130a, 130b may be produced and the gaseous product 130a, 130b may be removed from the container 121 as the electroless plating process proceeds. A gaseous product removing process may be performed on the container 121 during the electroless plating process. For example, a gaseous product such as hydrogen may be produced during a copper or nickel plating process. The gaseous product may be produced between the first electrical connector 107a, 107b, 107c and the second electrical connector 115a, 115b, 115c, which may adversely affect the electroless plating quality between the first electrical connector 107a, 107b, 107c and the second electrical connector 115a, 115b, 115c as the gaseous product 130a, 130b may cause voids in the electroless layer formed between them. Thus, by performing a gaseous removing process during the plating process to remove the gaseous product, the occurrence of the voids in the electroless layer formed between the first electrical connector 107a, 107b, 107c and the second electrical connector 115a, 115b, 115c may be reduced. Accordingly, the electroless bonding quality between the first electrical connector 107a, 107b, 107c and the second electrical connector 115a, 115b, 115c may be improved. The gaseous removing process may be performed by vacuum pumping.

In addition, in some embodiments where the gaseous product is removed by vacuum pumping, such process may also assist the first substrate 103 and the second substrate 111 to form an electroless layer surrounding the first electrical layer 107a, 107b, 107c and the second electrical layer 115a, 115b, 115c with a more uniform thickness as the vacuum pumping may create a lower pressure environment in the container 121 that may direct the electroless solution 127 toward the first electrical layer 107a, 107b, 107c and the second electrical layer 115a, 115b, 115c from all directions. For example, the difference between the first thickness of the first electroless layer 109 at the first side surface of the first electrical connector 107a, 107b, 107c and the second thickness of the first electroless layer 109 at the opposite second side surface of the first electrical connector 107a, 107b, 107c may be controlled within a range of about 1% to about 20% of the second thickness by such process.

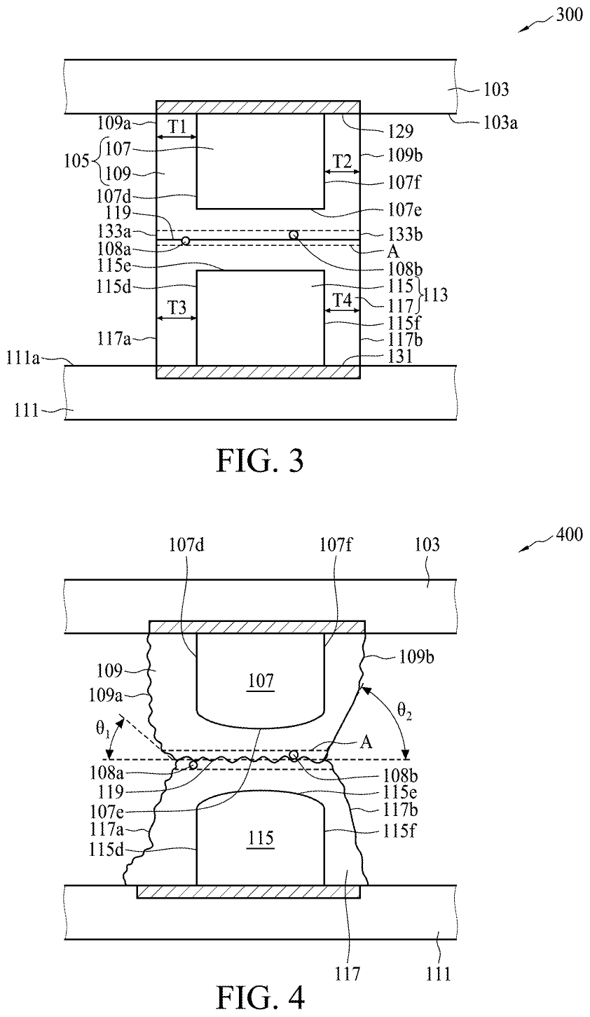

Referring to FIG. 1C, the first electroless layer 109 may be formed surrounding the first electrical connector 107a, 107b, 107c and the second electroless layer 117 may be formed surrounding the second electrical connector 115a, 115b, 115c by the electroless plating process. The first electroless layer 109 may connect or electroless bond to the second electroless layer 117 at an interface 119. Subsequently, an electroless semiconductor bonding structure such as the electroless semiconductor bonding structure 200, the electroless semiconductor bonding structure 300, and the electroless semiconductor bonding structure 400 illustrated in FIG. 2, FIG. 3, and FIG. 4, respectively may be obtained.

By forming the first electroless layer 109 surrounding the first electrical connector 107a, 107b, 107c and the second electroless layer 117 surrounding the second electrical connector 115a, 115b, 115c with an electroless plating process as described above, the first metal bonding structure 105 can be physically bonded to the second metal bonding structure 113 successfully at a lower temperature such as a temperature of 20° C. to 100° C. compared to those bonded by a thermal compression bonding technology, which typically requires a temperature of 200° C. to 250° C. Therefore, it may be more energy effective and may prevent the first electroless layer 109 and the second electroless layer 117 from melting during the metal to metal bonding process. In some embodiments, the first metal bonding structure 105 can be physically bonded to the second metal bonding structure 113 successfully at a temperature of about 20° C. to about 100° C., about 20° C. to about 90° C., about 20° C. to about 80° C., about 20° C. to about 70° C., about 20° C. to about 60° C., and about 20° C. to about 50° C. depending on the plating material to be used by the plating method described above.

FIG. 2 illustrates a cross-sectional view of an electroless semiconductor bonding structure 200 according to some embodiments of the present disclosure. The electroless semiconductor bonding structure 200 of FIG. 2 includes a first substrate 103 and a first metal bonding structure 105. The electroless semiconductor bonding structure 200 may be produced by an electroless plating method where an electroless solution, for example, flows from one side of the first electrical connector 107 toward the opposite side of the first electrical connector 107.

The first substrate 103 has a first surface 103a. The first substrate 103 may be a printed circuit board, a unit substrate, a strip substrate, or a combination thereof. A unit substrate may include, for example, a unit chip (e.g., a communication chip, a microprocessor chip, a graphics chip, or a microelectromechanical systems (MEMS) chip diced from a wafer), a unit package, a unit interposer, or a combination thereof. A strip substrate may include, for example, a plurality of unit substrates, unit chips (e.g., communication chips, microprocessor chips, graphics chips, or microelectromechanical systems (MEMS) chip diced from a wafer), unit packages, unit interposers, or a combination thereof. In some embodiments, the first substrate 103 is a unit chip.

The first substrate 103 may include at least one first pad 129. The first pad 129 may be disposed adjacent to the first surface 103a of the first substrate 103. In some embodiments, the first pad 129 is disposed on (e.g., physical contact or embedded in and exposed by) the first surface 103a of the first substrate 103. The first pad 129 may be, for example, a contact pad of a trace or a ball pad. In some embodiments, the first pad 129 is a contact pad of a trace. The first pad 129 may include, for example, one of, or a combination of, copper, gold, indium, tin, silver, palladium, osmium, iridium, ruthenium, titanium, magnesium, aluminum, cobalt, nickel, or zinc, or other metals or metal alloys.

The first metal bonding structure 105 may be disposed adjacent to the first surface 103a of the first substrate 103. The first metal bonding structure 105 may provide the first substrate 103 with external electrical connections. The first metal bonding structure 105 may be disposed adjacent to the first pad 129. In some embodiments, the first metal bonding structure 105 is disposed on respective first pad 129 and is physically bonded to and electrically connected to respective first pad 129. The first metal bonding structure 105 may comprise a first electrical connector 107 and a first electroless layer 109.

The first electrical connector 107 has a first side surface 107d, a second side surface 107f opposite to the first side surface 107d, and a first connector surface 107e extending from the first side surface 107d to the second side surface 107f. The first electrical connector 107 may be a pillar or a solder/stud bump. In some embodiments, the first electrical connector 107 is a pillar. The pillar 107 may comprise copper or another metal, or a metal alloy. In some embodiments, the pillar 107 comprises copper.

The first electroless layer 109 surrounds the first electrical connector 107. The first electroless layer 109 may cover at least a portion of the first side surface 107d, at least a portion of the second side surface 107f, and at least a portion of the first connector surface 107e. In some embodiments, the first electroless layer 109 covers the first side surface 107d, the second side surface 107f, and the first connector surface 107e entirely. The first electroless layer 109 may have a first thickness T1 at the first side surface 107d of the first electrical connector 107 and a second thickness T2 at the second side surface 107f of the first electrical connector 107. The first thickness T1 may be substantially the same or different from the second thickness T2. In some embodiments, the first thickness T1 is thicker than the second thickness T2. In some embodiments, the first thickness T1 is thinner than the second thickness T2.

In some embodiments such as those illustrated in FIG. 2, the first thickness T1 may be thicker than the second thickness T2 by a difference above about 30% of the second thickness T2. In some embodiments, the first thickness T1 is thicker than the second thickness T2 by a difference above about 32% of the second thickness T2. In some embodiments, the first thickness T1 is thicker than the second thickness T2 by a difference above about 34% of the second thickness T2. In some embodiments, the first thickness T1 is thicker than the second thickness T2 by a difference above about 36% of the second thickness T2. In some embodiments, the first thickness T1 is thicker than the second thickness T2 by a difference above about 38% of the second thickness T2. In some embodiments, the first thickness T1 is thicker than the second thickness T2 by a difference above about 40% of the second thickness T2. The first electroless layer 109 may comprise copper, nickel, gold, palladium, silver, or another metal, or a metal alloy. In some embodiments, the first electroless layer 109 comprises copper.

The semiconductor structure 100 may further comprise a second substrate 111 and a second metal bonding structure 113.

The second substrate 111 may be disposed adjacent to the first substrate 103. The second substrate 111 has a second surface 111a. The second surface 111a of the second substrate 111 may face the first surface 103a of the first substrate 103. The second substrate 111 may be a printed circuit board, a unit substrate, a strip substrate, or a combination thereof. A unit substrate may include, for example, a unit chip (e.g., a communication chip, a microprocessor chip, a graphics chip, or a microelectromechanical systems (MEMS) chip diced from a wafer), a unit package, a unit interposer, or a combination thereof. A strip substrate may include, for example, a plurality of unit substrates, unit chips (e.g., communication chips, microprocessor chips, graphics chips, or microelectromechanical systems (MEMS) chips diced from a wafer), unit packages, unit interposers, or a combination thereof. In some embodiments, the second substrate 111 is a unit chip.

The second substrate 111 may include at least one second pad 131. The second pad 131 may be disposed adjacent to the second surface 111a of the second substrate 111. In some embodiments, the second pad 131 is disposed on (e.g., physical contact or embedded in and exposed by) the second surface 111a of the second substrate 111. The second pad 131 may be, for example, a contact pad of a trace or a ball pad. In some embodiments, the second pad 131 is a contact pad of a trace. The second pad 131 may include, for example, one of, or a combination of, copper, gold, indium, tin, silver, palladium, osmium, iridium, ruthenium, titanium, magnesium, aluminum, cobalt, nickel, or zinc, or other metals or metal alloys.

The second metal bonding structure 113 may be disposed adjacent to the second surface 111a of the second substrate 111. The second metal bonding structure 113 may provide the second substrate 111 with external electrical connections. The second metal bonding structure 113 may be disposed adjacent to the second pad 131. In some embodiments, the second metal bonding structure 113 is disposed on respective second pad 131 and is physically bonded to and electrically connected to respective second pad 131. The second metal bonding structure 113 may comprise a second electrical connector 115 and a second electroless layer 117.

The second electrical connector 115 has a third side surface 115d, a fourth side surface 115f opposite to the third side surface 115d, and a second connector surface 115e extending from the third side surface 115d to the fourth side surface 115f. The second electrical connector 115 may be a pillar or a solder/stud bump. In some embodiments, the second electrical connector 115 is a pillar. The pillar 115 may comprise copper, or another metal, or a metal alloy. In some embodiments, the pillar 115 comprises copper.

The second electroless layer 117 surrounds the second electrical connector 115. The second electroless layer 117 may cover at least a portion of the third side surface 115d, at least a portion of the fourth side surface 115f, and at least a portion of the second connector surface 115e. In some embodiments, the second electroless layer 117 covers the third side surface 115d, the fourth side surface 115f, and the second connector surface 115e entirely. The second electroless layer 117 may have a third thickness T3 at the third side surface 115d of the second electrical connector 115 and a fourth thickness T4 at the fourth side surface 115f of the second electrical connector 115. The third thickness T3 may be substantially the same or different from the fourth thickness T4. In some embodiments, the third thickness T3 is thicker than the fourth thickness T4. In some embodiments, the third thickness T3 is thinner than the fourth thickness T4. In some embodiments where the first thickness T1 and the third thickness T3 are at the same side, the first thickness T1 is thicker than the second thickness T2 and the third thickness T3 is thicker than the fourth thickness T4.

In some embodiments such as those illustrated in FIG. 2, the third thickness T3 may be thicker than the fourth thickness T4 by a difference above about 30% of the fourth thickness T4. In some embodiments, the third thickness T3 is thicker than the fourth thickness T4 by a difference above about 32% of the fourth thickness T4. In some embodiments, the third thickness T3 is thicker than the fourth thickness T4 by a difference above about 34% of the fourth thickness T4. In some embodiments, the third thickness T3 is thicker than the fourth thickness T4 by a difference above about 36% of the fourth thickness T4. In some embodiments, the third thickness T3 is thicker than the fourth thickness T4 by a difference above about 38% of the fourth thickness T4. In some embodiments, the third thickness T3 is thicker than the fourth thickness T4 by a difference above about 40% of the fourth thickness T4. The second electroless layer 117 may comprise copper, nickel, gold, palladium, silver, or another metal, or a metal alloy. In some embodiments, the second electroless layer 117 comprises copper.

The first metal bonding structure 105 may be disposed adjacent to the second metal bonding structure 113. The first metal bonding structure 105 may be physically bonded to the second metal bonding structure 113. In some embodiments, the first metal bonding structure 105 is physically bonded to and electrically connected to the second metal bonding structure 113 by electroless bonding. The first electroless layer 109 of the first metal bonding structure 105 may connect to the second electroless layer 117 of the second metal bonding structure 113 at an interface 119 between the first electrical connector 107 and the second electrical connector 115 by electroless bonding. In some embodiments where the first thickness T1 is thicker than the second thickness T2 by a difference above about 30% of the second thickness T2, it may also be accompanied with a plurality of voids 108a, 108b existing at the interface 119, existing in the first electroless layer 109, existing in the second electroless layer 117, surrounding the first electrical connector 107, and/or surrounding the second electrical connector 115.

In some embodiments, voids 108a, 108b exist between the first electrical connector 107 and the second electrical connector 115. In some embodiments, voids 108a, 108b exist at or proximal to the interface 119. In some embodiments, voids 108a, 108b exist in the portion of the first electroless layer 109 between the interface 119 and the first electrical connector 107. In some embodiments, voids 108a, 108b exist in the portion of the second electroless layer 117 between the interface 119 and the second electrical connector 115.

Voids 108a, 108b in the semiconductor structure 200 illustrated in FIG. 2 may occupy a cross-section area of above about 10% of the total cross-section area of region A illustrated in FIG. 2. In some embodiments, voids 108a, 108b occupy a cross-section area of above about 12% of the total cross-section area of region A. In some embodiments, voids 108a, 108b occupy a cross-section area of above about 14% of the total cross-section area of region A. In some embodiments, voids 108a, 108b occupy a cross-section area of above about 15% of the total cross-section area of region A. In some embodiments, voids 108a, 108b occupy a cross-section area of above about 16% of the total cross-section area of region A.

Still referring to FIG.2, a tangent line 133c of the upmost portion of a first void 108b, a tangent line 133d of the lowest portion of the second void 108a, a side surface 133a extending from an outmost side surface 109a of the first metal bonding structure 105 to an outmost side surface 117a of the second metal bonding structure 113, and an opposite side surface 133b extending from an opposite outmost side surface 109b of the first metal bonding structure 105 to an opposite outmost side surface 117b of the second metal bonding structure 113 define region A.

FIG. 3 illustrates a cross-sectional view of an electroless semiconductor bonding structure 300 according to some embodiments of the present disclosure. The electroless semiconductor bonding structure 300 illustrated in FIG. 3 is similar to that illustrated in FIG. 2 with a difference including that the methods of forming the first electroless layer 109 and the second electroless layer 117 may be different, where an electroless solution may flow toward the first electrical connector 107 from different directions, the first substrate 103 and the second substrate 111 may stand still in a still electroless solution, or the electroless solution may be provided to the first substrate 103 and the second substrate 111 intermittently when forming the first electroless layer 109 and the second electroless layer 117. In addition, a gaseous product removing process may be performed. The electroless semiconductor bonding structure 300 obtained in accordance with the plating method described above may have a more uniform first electroless layer 109 on the first electrical connector 107 where the difference between the first thickness T1 and the second thickness T2 is within a certain range and voids 108a, 108b may be substantially free at or proximal to the interface 119.

The first thickness T1 may be thicker than the second thickness T2 by a difference between about 1% and about 20% of the second thickness T2. In some embodiments, the first thickness T1 is thicker than the second thickness T2 by a difference between about 1% and about 18% of the second thickness T2. In some embodiments, the first thickness T1 is thicker than the second thickness T2 by a difference between about 1% and about 16% of the second thickness T2. In some embodiments, the first thickness T1 is thicker than the second thickness T2 by a difference between about 1% and about 14% of the second thickness T2. In some embodiments, the first thickness T1 is thicker than the second thickness T2 by a difference between about 1% and about 12% of the second thickness T2. In some embodiments, the first thickness T1 is thicker than the second thickness T2 by a difference between about 1% and about 10% of the second thickness T2. In some embodiments, the first thickness T1 is thicker than the second thickness T2 by a difference between about 1% and about 8% of the second thickness T2. In some embodiments, the first thickness T1 is thicker than the second thickness T2 by a difference between about 1% and about 6% of the second thickness T2. In some embodiments, the first thickness T1 is thicker than the second thickness T2 by a difference between about 1% and about 4% of the second thickness T2. In some embodiments, the first thickness T1 is thicker than the second thickness T2 by a difference between about 1% and about 2% of the second thickness T2. In some embodiments where the first thickness T1 is thicker than the second thickness T2 by a difference between about 1% and about 10% of the second thickness T2, the first thickness Ti may be considered substantially the same with the second thickness T2.

The third thickness T3 may have the same thickness trend with the fourth thickness T4 as the first thickness T1 does with the second thickness T2, which is not further described for brevity.

In addition, by utilizing the electroless plating process described above, less voids 108a, 108b may exist between the first electrical connector 107 and the second electrical connector 115. In some embodiments, voids 108a, 108b may occupy a cross-section area of between about 1% and about 10% of the total cross-section area of region A of the semiconductor structure illustrated in FIG. 3 as the gaseous product removing process may remove a gaseous product produced during the plating process that may cause voids in the first electroless layer 109, the second electroless layer 117, or both. In some embodiments where voids occupy a cross-section area of between about 1% and about 10% of the total cross-section area of region A, voids may be considered substantially free at or proximal to the interface 119. In some embodiments, voids 108a, 108b are substantially free in the portion of the first electroless layer 109 between the interface 119 and the first electrical connector 107. In some embodiments, voids 108a, 108b are substantially free in the portion of the second electroless layer 117 between the interface 119 and the second electrical connector 115. In some embodiments, voids 108a, 108b are substantially free between the first electrical connector 107 and the second electrical connector 115. As voids 108a, 108b can be substantially free at or proximal to the interface 119 between the first metal bonding structure 105 and the second metal bonding structure 113, the first metal bonding structure 105 can be physically bonded to the second metal bonding structure 113 continuously without any disruption. Therefore, the electroless bonding quality and thus the electrical connection between the first metal bonding structure 105 and the second metal bonding structure 113 can be improved.

In some embodiments, a percentage of a total cross-section area of the plurality of voids 108a, 108b to the total cross-section area of region A is between about 1% and about 10%. In some embodiments, a percentage of a total cross-section area of the plurality of voids 108a, 108b to the total cross-section area of region A is between about 1% and about 8%. In some embodiments, a percentage of a total cross-section area of the plurality of voids 108a, 108b to the total cross-section area of region A is between about 1% and about 6%. In some embodiments, a percentage of a total cross-section area of the plurality of voids 108a, 108b to the total cross-section area of region A is between about 1% and about 4%. In some embodiments, a percentage of a total cross-section area of the plurality of voids 108a, 108b to the total cross-section area of region A is between about 1% and about 2%.

FIG. 4 illustrates a cross-sectional view of an electroless semiconductor bonding structure 400 according to some embodiments of the present disclosure. The electroless semiconductor bonding structure 400 illustrated in FIG. 4 is similar to that illustrated in FIG. 3 with a difference including that the fifth side surface 109a and sixth side surface 109b of the first electroless layer 109 and the seventh side surface 117a and eighth side surface 117b of the second electroless layer 117 are slightly curved and have an uneven surface and the interface 119 has an uneven surface.

In some embodiments, the fifth side surface 109a and sixth side surface 109b of the first electroless layer 109 are rougher than the first side surface 107d and the second side surface 107f of the first electrical connector 107. In some embodiments, the seventh side surface 117a and eighth side surface 117b of the second electroless layer 117 are rougher than the third side surface 115d and the fourth side surface 115f of the second electrical connector 115.

By providing the first electroless layer 109 with a rougher surface than that of the first electrical connector 107 or the second electroless layer 117 with a rougher surface than that of the second electrical connector 115, an encapsulant may be adhered to the first electrical connector 107 or the second electroless layer 117 better.

In some embodiments, the fifth side surface 109a of the first electroless layer 109 forms a first angle θ₁ with respect to the interface 119 and the sixth side surface 109b of the first electroless layer 109 forms a second angle θ₂ with respect to the interface 119, and the first angle this different from the second angle θ₂.

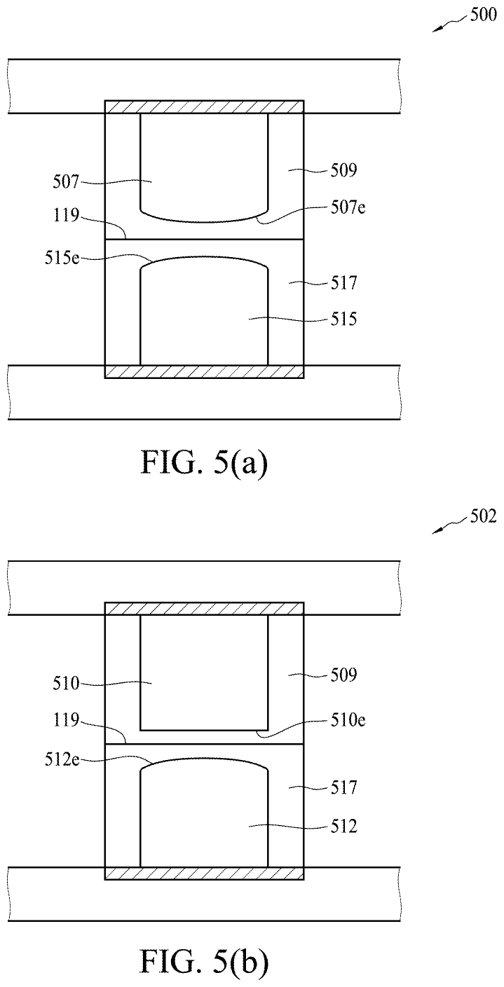

FIG. 5(a) illustrates a cross-sectional view of an electroless semiconductor bonding structure 500 according to some embodiments of the present disclosure. The electroless semiconductor bonding structure 500 illustrated in FIG. 5(a) is similar to that illustrated in FIG. 3 with a difference including that the shape of the first connector surface 507e of the first electrical connector 507 and the shape of the second connector surface 515e of the second electrical connector 515 can be different from those illustrated in FIG. 3.

The first connector surface 507e of the first electrical connector 507 may be substantially flat or protrude toward the interface 119 between the first electrical connector 507 and the second electrical connector 515. In some embodiments, the first connector surface 507e of the first electrical connector 507 has a peak toward the interface 119 between the first electrical connector 507 and the second electrical connector 515. In some embodiments, the first connector surface 507e of the first electrical connector 507 curves. In some embodiments, the first connector surface 507e of the first electrical connector 507 curves outwardly toward the interface 119 between the first electrical connector 507 and the second electrical connector 515.

The second connector surface 515e of the second electrical connector 515 may be substantially flat or protrude toward the interface 119 between the first electrical connector 507 and the second electrical connector 515. In some embodiments, the second connector surface 515e of the second electrical connector 515 has a peak toward the interface 119 between the first electrical connector 507 and the second electrical connector 515. In some embodiments, the second connector surface 515e of the second electrical connector 515 curves. In some embodiments, the second connector surface 515e of the second electrical connector 515 curves outwardly toward the interface 119 between the first electrical connector 507 and the second electrical connector 515.

By disposing at least one of the first connector surface 507e of the first electrical connector 507 and the second connector surface 515e of the second electrical connector 515 to have a surface protruding toward the interface 119 between the first electrical connector 507 and the second electrical connector 515, voids 108a, 108b can be substantially free at or proximal to the interface 119 between the first metal bonding structure 105 and the second metal bonding structure 113 as the protrusion surface of the first connector surface 507e and the second connector surface 515e may shorten the distance between the first electrical connector 507 and the second electrical connector 515 so the first electroless layer 509 and the second electroless layer 517 formed in conformity with the shape of the first connector surface 507e and the second connector surface 515e can connect to each other more easily and completely. Thus, the first metal bonding structure 105 can be physically bonded to the second metal bonding structure 113 continuously without any disruption. Therefore, the electroless bonding quality and thus the electrical connection between the first metal bonding structure 105 and the second metal bonding structure 113 can be improved.

FIG. 5(b) illustrates a cross-sectional view of an electroless semiconductor bonding structure 502 according to some embodiments of the present disclosure. The electroless semiconductor bonding structure 502 illustrated in FIG. 5(b) is similar to that illustrated in FIG. 5(a) with a difference including that one of the first connector surface 510e of the first electrical connector 510 and the second connector surface 512e of the second electrical connector 512 protrudes toward the interface 119 between the first electrical connector 510 and the second electrical connector 512 and the other is substantially flat.

As described above, disposing at least one of the first connector surface 510e of the first electrical connector 510 and the second connector surface 512e of the second electrical connector 512 to protrude toward the interface 119 between the first electrical connector 510 and the second electrical connector 512 can improve the electroless bonding quality and thus the electrical connection between the first metal bonding structure 105 and the second metal bonding structure 113 as the protrusion surface may shorten the distance between the first electrical connector 507 and the second electrical connector 515 and allow the first electroless layer 509 and the second metal layer 317 formed in conformity with the shape of the first connector surface 507e and the second connector surface 515e to connect to each other more easily and completely.

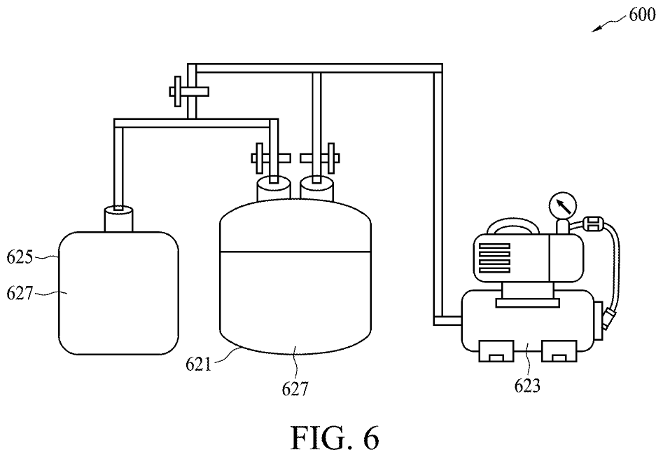

FIG. 6 illustrates an electroless plating system 600 according to some embodiments of the present disclosure. The electroless plating system 600 of FIG. 6 includes a container 621 and a vacuum pump 623. It should be noted that some process units may be eliminated from the figure for the sake of conciseness.

The container 621 should be so configured that at least one first substrate 103 can be placed therein. In some embodiments, the container 621 is so configured that it can accommodate at least one first substrate 103 and at least one second substrate 111 facing the first substrate 103. In addition, the container 621 should have sufficient space for accommodating an electroless solution for plating the first substrate 103 and/or the second substrate 111.

The container 621 may further contain an electroless solution 627. The electroless solution 627 should contain compounds that can effectively plate the first substrate 103 and/or the second substrate 111. In some embodiments, the electroless solution 627 contains at least one component selected from tetrasoldium ethylenediaminetetraacetate (tetrasodium EDTA), copper sulfate, sodium hydroxide, 2,2′-bipyridine, formaldehyde, and water. In some embodiments, the electroless solution 627 contains tetrasoldium ethylenediaminetetraacetate, copper sulfate, and sodium hydroxide.

In some embodiments where the tetrasoldium ethylenediaminetetraacetate is included in the electroless solution 627, the content of the tetrasoldium ethylenediaminetetraacetate is less than about 5% by weight of the solution, less than about 4.8% by weight of the solution, less than about 4.6% by weight of the solution, less than about 4.4% by weight of the solution, less than about 4.2% by weight of the solution, less than about 4% by weight of the solution, less than about 3.8% by weight of the solution, less than about 3.6% by weight of the solution, less than about 3.4% by weight of the solution, less than about 3.2% by weight of the solution, less than about 3% by weight of the solution, less than about 2.8% by weight of the solution, or less than about 2.7% by weight of the solution.

In some embodiments where the copper sulfate is included in the electroless solution 627, the content of the copper sulfate is less than about 3% by weight of the solution, less than about 2.8% by weight of the solution, less than about 2.6% by weight of the solution, less than about 2.4% by weight of the solution, less than about 2.2% by weight of the solution, less than about 2% by weight of the solution, less than about 1.8% by weight of the solution, less than about 1.6% by weight of the solution, less than about 1.4% by weight of the solution, less than about 1.2% by weight of the solution, less than about 1% by weight of the solution, less than about 0.8% by weight of the solution, or less than about 0.7% by weight of the solution.

In some embodiments where the sodium hydroxide is included in the electroless solution 627, the content of the sodium hydroxide is less than about 3% by weight of the solution, less than about 2.8% by weight of the solution, less than about 2.6% by weight of the solution, less than about 2.4% by weight of the solution, less than about 2.2% by weight of the solution, less than about 2% by weight of the solution, less than about 1.8% by weight of the solution, less than about 1.6% by weight of the solution, less than about 1.4% by weight of the solution, less than about 1.2% by weight of the solution, less than about 1% by weight of the solution, less than about 0.8% by weight of the solution, or less than about 0.6% by weight of the solution.

In some embodiments where the 2,2′-bipyridine is included in the electroless solution 627, the content of the 2,2′-bipyridine is less than about 1% by weight of the solution, less than about 0.8% by weight of the solution, less than about 0.7% by weight of the solution, less than about 0.6% by weight of the solution, less than about 0.5% by weight of the solution, less than about 0.4% by weight of the solution, less than about 0.3% by weight of the solution, less than about 0.2% by weight of the solution, less than about 0.1% by weight of the solution.

In some embodiments where the formaldehyde is included in the electroless solution 627, the content of the formaldehyde is less than about 1% by weight of the solution, less than about 0.8% by weight of the solution, less than about 0.7% by weight of the solution, less than about 0.6% by weight of the solution, less than about 0.5% by weight of the solution, less than about 0.4% by weight of the solution, less than about 0.3% by weight of the solution, less than about 0.2% by weight of the solution, less than about 0.1% by weight of the solution.

In some embodiments, the content of water is about 87% to about 96% by weight of the solution.

The vacuum pump 623 may connect to the container 621. The vacuum pump 623 may connect to the container 621 through a fluid communication component. In some embodiments, the vacuum pump 623 connects to the container 621 through a pipe. The vacuum pump 623 is utilized for removing gaseous product. By connecting the vacuum pump 623 to the container 621, the gaseous product produced during the electroless plating process in the container 621 may be removed by the vacuum pump 623. The gaseous product may be an unwanted gaseous product, such as hydrogen gas produced during a copper plating process or a nickel plating process.

The electroless plating system 600 may further include an electroless solution container 625. The electroless solution container 625 is utilized for storing an electroless solution. The elctroless solution container 625 may or may not connect to the substrate container 621. The electroless solution container 625 may connect to the substrate container 621 through a fluid communication component. In some embodiments, the electroless solution container 625 connects to the substrate container 621 through a pipe.

In some embodiments where the electroless solution container 625 connects to the substrate container 621, the electroless solution 627 described above may be provided to the substrate container 621 continuously or intermittently by the electroless solution container 625. In some embodiments where the electroless solution container 625 does not connect to the substrate container 621, the electroless solution 627 described above may be provided to the substrate container 621 by means that can move the electroless solution 627 from one place to another, such as by manpower or any suitable transfer techniques.

As used herein, the singular terms “a,” “an,” and “the” may include plural referents unless the context clearly dictates otherwise. In the description of some embodiments, a component provided “on or “over” another component can encompass cases where the former component is directly on (e.g., in physical contact with) the later component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A method of electrolessly plating a substrate, comprising:
disposing an electroless solution in a container;
disposing a first substrate in the container, the first substrate having an exposed metal surface;
removing a gaseous product from the container; and
forming a first metal layer on the exposed metal surface of the first substrate.

2. The method of claim 1, wherein the step of disposing the electroless solution comprises providing the container with the electroless solution continuously.

3. The method of claim 1, wherein the step of disposing the electroless solution comprises flowing the electroless solution from a first side of the container to a second side of the container.

4. The method of claim 1, wherein the step of disposing the electroless solution comprises flowing the electroless solution toward the first substrate in at least two directions.

5. The method of claim 4, wherein flowing the electroless solution toward the first substrate in at least two directions and the step of removing the gaseous product from the first substrate are achieved by vacuum pumping.

6. The method of claim 1, wherein the first substrate stands still in the electroless solution.

7. The method of claim 1, wherein the step of disposing the electroless solution comprises providing the electroless solution to the container intermittently.

8. The method of claim 1, wherein the gaseous product includes hydrogen gas.

9. The method of claim 1, wherein the first substrate further comprises a first electrical connector disposed adjacent to the exposed metal surface of the first substrate.

10-20. (canceled)

21. The method of claim 1, further comprising vibrating the container.

22. The method of claim 3, wherein the first substrate is disposed over the first side of the container.

23. The method of claim 4, wherein the electroless solution is flowed toward the first substrate in opposite directions.

24. The method of claim 1, further comprising disposing a second substrate in the container and facing the first substrate, the second substrate having an exposed metal face, and further comprising forming a second metal layer on the exposed metal surface of the second substrate.

25. The method of claim 24, wherein the second metal layer connects to the first metal layer at an interface.

26. The method of claim 24, wherein the first substrate further comprises a first electrical connector disposed adjacent to the exposed metal surface of the first substrate, the second substrate further comprises a second electrical connector disposed adjacent to the exposed metal surface of the second substrate, and the first electrical connector aligns with the second electrical connector.

27. The method of claim 26, wherein the first metal layer is formed surrounding the first electrical connector and the second metal layer is formed surrounding the second electrical connector and connecting to the first metal layer at an interface.

28. The method of claim 24, wherein the step of disposing the electroless solution comprises flowing the electroless solution from the first substrate toward the second substrate.

29. The method of claim 9, wherein the first metal layer is formed surrounding the first electrical connector.

30. The method of claim 9, wherein the first metal layer is formed embedding the first electrical connector.

31. The method of claim 9, wherein the step of disposing the electroless solution comprises flowing the electroless solution toward the first electrical connector in at least two directions.
